(19) United States
(12) Patent Application Publication
(10) Pub. No.: US 2026/0282224 A1
(43) Pub. Date: Sep. 17, 2026

(54) CIRCUIT BOARD AND MANUFACTURING METHOD OF CIRCUIT BOARD

(71) Applicant: SAMSUNG ELECTRO-MECHANICS CO., LTD., Suwon-si (KR)

(72) Inventor: Youngwoong Cho, Suwon-si (KR)

(73) Assignee: SAMSUNG ELECTRO-MECHANICS CO., LTD., Suwon-si (KR)

(21) Appl. No.: 19/277,249

(22) Filed: Jul. 22, 2025

(30) Foreign Application Priority Data
Mar. 13, 2025 (KR) 10-2025-0032786

(51) Int. Cl. H05K 1/11; H05K 1/09; H05K 3/40; H05K 3/46

(52) U.S. Cl. CPC H05K 1/112; H05K 1/09; H05K 3/4038; H05K 3/4644

(57) ABSTRACT

A circuit board includes an insulating layer having a via hole, a via filling the via hole, a circuit layer disposed on the insulating layer and including a pad connected to the via and a circuit wiring spaced apart from the pad, and a carbon pattern layer disposed between the circuit layer and a surface of the insulating layer.

### CROSS-REFERENCE TO RELATED APPLICATION

This application claims priority to and the benefit of Korean Patent Application No. 10-2025-0032786 filed with the Korean Intellectual Property Office on Mar. 13, 2025, the entire contents of which are incorporated herein by reference.

### BACKGROUND OF THE INVENTION

### (a) Field of the Invention

The present disclosure relates to a circuit board and a manufacturing method thereof.

### (b) Description of the Related Art

As electronic products become more miniaturized and multifunctional, fine pitch pattern implementation of the printed circuit board (PCB) is required. In a process of semiconductor chip, fine patterns at a nanometer (nm) level may be implemented, while in a process of the printed circuit board, patterns at a micrometer (μm) level may be implemented. Accordingly, a difference in the pattern gap between the semiconductor chip and the printed circuit board occurs. To solve this pattern gap problem, when implementing Package on Package, chip mounting is performed by placing an interposer substrate in the middle, but this increases the complexity of the manufacturing process and has a negative effect on signal characteristics.

There have been various attempts to implement fine patterns in printed circuit board manufacturing, but there are technical limitations in implementing fine patterns at the nanometer level due to the resolution limits of photo-sensitive materials and interlayer adhesion problems. In particular, when using substrate materials with low thermal expansion characteristics, achieving a technological balance between ensuring interlayer adhesion and forming fine patterns is emerging as an important task. Accordingly, there is an urgent need to develop a new technology that can implement high-resolution fine patterns on the printed circuit board while ensuring stable interlayer adhesion.

### SUMMARY OF THE INVENTION

The present disclosure may provide a circuit board having a nanometer-level fine pattern formed thereon using a positive type liquid photo-sensitive material.

The present disclosure may provide a manufacturing method of circuit board capable of implementing a nanometer-level fine pattern on the circuit board using a positive type liquid photo-sensitive material and capable of manufacturing a high-performance package product by ensuring interlayer adhesion

The object of the present disclosure is not limited to the above-described object, and it may be expanded in various ways in the range of the ideas and the areas of the present disclosure.

In one aspect, a circuit board includes an insulating layer having a via hole; a via filling the via hole; a circuit layer disposed on the insulating layer, and including a pad connected to the via and a circuit wiring spaced apart from the pad; and a carbon pattern layer disposed between the circuit layer and a surface of the insulating layer.

The carbon pattern layer may include a graphite layer.

The circuit layer may include a metal layer, and the carbon pattern layer may be disposed between the metal layer and the insulating layer.

The carbon pattern layer may not exist on a surface of the insulating layer where the pad or the circuit wiring is not disposed.

The insulating layer may include a first insulating layer having a through via hole penetrating in a first direction, and a second insulating layer covering the first insulating layer and having a stack via hole.

The via may fill the stack via hole and include a stack via penetrating the second insulating layer.

The via may include a through via that fills the through via hole and is connected to the stack via.

The through via may include a through portion filling the through via hole; and a land portion extending from the through portion in a second direction intersecting the first direction and disposed on the first insulating layer.

The stack via may penetrate the second insulating layer and be connected to the land portion of the through via.

The circuit layer may include a first circuit layer disposed on the first insulating layer and spaced apart from the land portion and a second circuit layer disposed on the second insulating layer, and carbon pattern layer may be disposed at the second circuit layer adjacent to a surface of the second insulating layer

The carbon pattern layer may be disposed between the pad and the surface of the insulating layer or disposed between the circuit wiring and the surface of the insulating layer.

In another aspect, a manufacturing method of a circuit board includes forming a via hole penetrating an insulating layer; forming a seed layer on a surface of the insulating layer in which the via hole is formed; forming a first mask pattern on the first seed layer to expose the seed layer of the via hole and its surrounding area; forming a via formation layer on the seed layer exposed by the first mask pattern; exposing the insulating layer by removing the first mask pattern and the via formation layer disposed on the insulating layer; applying a carbon layer to a surface of the exposed insulating layer; forming a second mask pattern on the carbon layer; forming a circuit layer on the carbon layer exposed by the second mask pattern; exposing the carbon layer by removing the second mask pattern disposed on the carbon layer; and removing the exposed carbon layer.

Applying the carbon layer may include applying colloidal graphite.

Forming the second mask pattern may include forming a positive photoresist by applying a positive liquid photosensitive material.

Removing the exposed carbon layer may include removing the exposed carbon layer using a mixed solution of water and ethanol.

Exposing the insulating layer may include removing the first mask pattern and at least a portion of the via formation layer through polishing.

Forming the seed layer may include forming the seed layer through electroless plating on the via hole and the surface of the insulating layer.

Forming the first mask pattern may include forming a negative photoresist.

Forming the via formation layer may include forming a via that fills an inside of the via hole.

The insulating layer may include a first insulating layer having a through via hole penetrating in a first direction and a second insulating layer covering the first insulating layer and having a stack via hole, and the via may fill the stack via hole and include a stack via penetrating the second insulating layer.

According to the present disclosure, a nanometer-level fine pattern may be implemented using a positive-type liquid photosensitive material, thereby minimizing a pattern gap between a semiconductor chip and a circuit board.

According to the present disclosure, stable adhesion between a prepreg layer and a copper pattern may be secured, thereby improving product reliability.

According to the present disclosure, a high-performance package product may be implemented by improving signal characteristics through a shortened signal path due to the removal of the interposer board. In addition, the present disclosure may contribute to the miniaturization of electronic products by reducing the thickness of the overall package.

### BRIEF DESCRIPTION OF THE DRAWINGS

FIG. 1 is a cross-sectional view schematically illustrating a structure of a circuit board according to an embodiment.

FIGS. 2 to 13 are process cross-sectional views illustrating a method for manufacturing a circuit board according to an embodiment.

FIG. 14 is a cross-sectional view schematically illustrating a structure of a circuit board according to another embodiment.

FIG. 15 is a process cross-sectional illustrating a method for manufacturing the circuit board shown in FIG. 14.

### DETAILED DESCRIPTION OF THE EMBODIMENTS

Hereinafter, various embodiments of the present disclosure will be described in detail so that a person of ordinary skill in the technical field to which the present disclosure belongs can easily implement it with reference to the accompanying drawings. In order to clearly describe the present disclosure, parts unrelated to the description are omitted in the drawings, and the same reference numerals are designated to the same or similar elements throughout the specification.

In addition, some elements in the accompanying drawings are exaggerated, omitted, or schematically illustrated, and the size of each component does not fully reflect the actual size. The accompanying drawings are provided only in order to allow embodiments disclosed in the present specification to be easily understood and are not to be interpreted as limiting the technical concept disclosed in the present specification, and it is to be understood that the present disclosure includes all modifications, equivalents, and substitutions without departing from the scope and concept of the present disclosure.

Terms including ordinal numbers such as first, second, and the like will be used only to describe various components and are not to be interpreted as limiting these components. The terms are only used to differentiate one component from other components.

Furthermore, it will be understood that when an element such as a layer, film, region, or substrate is referred to as being “on” another element, it can be directly on the other element or intervening elements may also be present. In contrast, when an element is referred to as being “directly on” another element, there are no intervening elements present. In addition, these positional relationships are independent of the direction of gravity.

It will be further understood that terms “comprises/includes” or “have” used throughout the specification specify the presence of stated features, numerals, steps, operations, elements, parts, or a combination thereof, but do not preclude the presence or addition of one or more other features, numerals, steps, operations, elements, parts, or a combination thereof. Accordingly, unless explicitly stated otherwise, the word “comprise” and variations such as “comprises” or “comprising” will be understood to imply the inclusion of stated components but not the exclusion of any other components.

Furthermore, throughout the specification, the phrase “in a plan view” means when an object portion is viewed from above, and the phrase “in a cross-sectional view” means when a cross-section taken by vertically cutting an object portion is viewed from the side.

Throughout the specification, “connected” means that two or more elements are not only directly connected, but two or more elements may be connected indirectly through other elements, physically connected as well as being electrically connected, or it may be referred to by different names depending on the location or function but may mean integral.

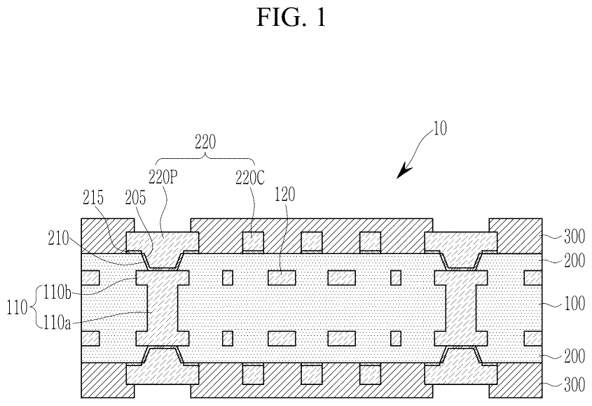

FIG. 1 is a cross-sectional view schematically illustrating a structure of a circuit board according to an embodiment.

Referring to FIG. 1, the circuit board 10 according to an embodiment may include a first insulating layer 100, a first circuit layer 120, a through via 110, a second insulating layer 200, a second circuit layer 220, and a carbon pattern layer 215 to provide a stable transmission path of an electrical signal through a multilayer wiring structure. The carbon pattern layer 215 may be disposed between the circuit layer and a surface of the insulating layer.

The first insulating layer 100 and the second insulating layer 200 may include an insulating material for interlayer insulation. The insulating material may include a thermosetting resin such as an epoxy resin, a thermoplastic resin such as polyimide, or these resins containing an inorganic filler such as silica and a reinforcing material such as glass fiber. The insulating material may be a photosensitive material or non-photosensitive material. For example, Solder Resist (SR), Ajinomoto-Build up Film (ABF), FR-4, Bismaleimide Triazine (BT), Resin Coated Copper (RCC) or Copper Clad Laminate (CCL), etc. may be used as the insulating material, but are not limited thereto. The insulating material may include polymer material. For example, prepreg may be used, but is not limited thereto. The first insulating layer 100 may be composed of multiple thin layers laminated to secure the required thickness and properties.

The first insulating layer 100 may have a through via hole penetrating in a first direction therein. The first direction is a stacking direction or a direction perpendicular to the surface of the insulating layer. The through via 110 may include a through portion 110a extending in the first direction to cover an inner wall of the through via hole, and a land portion 110b extending in a second direction intersecting the first direction from both ends of the through portion 110a. The through portion 110a may provide electrical connections in a vertical direction

Here, the second direction may be a direction that intersects the first direction and is parallel to the surface of the insulating layer, thereby forming a three-dimensional electrical connection structure.

A metal material with excellent electrical conductivity may be used as a material for each of the through via 110 and a stack via 210. The metal material may include copper (Cu), aluminum (Al), silver (Ag), tin (Sn), gold (Au), nickel (Ni), lead (Pb), titanium (Ti), or an alloy thereof. Each of the through via 110 and the stack via 210 may include a signal via, a ground via, a power via, and the like according to a circuit design. The stack via 210 may penetrate the second insulating layer 200 and be connected to the land portion 110b of the through via 110.

Each of the first circuit layer 120 and the second circuit layer 220 may efficiently transmit signals within the circuit board. The first circuit layer 120 may be disposed on the first insulating layer 100 and spaced apart from the land portion 110b, and the second circuit layer 220 may be disposed on the second insulating layer 200. A material with excellent conductivity and reliability may be used as a material for each of the first circuit layer 120 and the second circuit layer 220. The material may include copper, aluminum, silver, tin, gold, nickel, lead, titanium, or an alloy thereof. Each of the first circuit layer 120 and the second circuit layer 220 may perform various functions depending on the design, such as a ground pattern, a power pattern, and a signal pattern. Each of these patterns can have the form of a line, a plane, or a pad, which allows for a variety of circuit designs. In the case of a circuit layer located at the outermost layer among multiple circuit layers, it can function as a connection pad for connection with another substrate or component, thereby providing electrical connectivity with the outside.

The second circuit layer 220 may include a pad 220P and a circuit wiring 220C. Since fine pattern formation is possible, a line width/spacing (L/S) of less than 5 micrometers may be implemented. The pad 220P of the second circuit layer 220 may be stably connected to the first circuit layer 120 through the stack via 210 penetrating the second insulating layer 200. This may contribute to high-density circuit implementation and improved reliability of signal transmission.

The carbon pattern layer 215 is a layer that stably forms the second circuit layer 220 on the second insulating layer 200. The carbon pattern layer 215 may include conductive graphite and effectively contribute to securing adhesion of the second circuit layer 220 to the second insulating layer 200. The carbon pattern layer 215 may be disposed at the second circuit layer 220 adjacent to a surface of the second insulating layer 200. Specifically, the carbon pattern layer 215 may be disposed between the pad 220P and the surface of the second insulating layer 200, or between the circuit wiring 220C and the surface of the second insulating layer 200. In addition, when the second circuit layer 220 includes a metal layer, the carbon pattern layer 215 may be disposed between the metal layer and the second insulating layer 200. The carbon pattern layer 215 may not exist on a surface of the second insulating layer 200 where the pad 220P or the circuit wiring 220C is not disposed. The carbon pattern layer 215 may be formed to a thickness of several nanometers (nm) and thus does not form a step on the second insulating layer 200, which may help improve the stability and reliability of subsequent processes.

A protective layer 300 may be formed on the second insulating layer 200 to cover one surface of the second insulating layer 200 and selectively expose at least a portion of the pad 220P of the second circuit layer 220. The protective layer 300 may effectively protect internal components from external physical and chemical damage, and may simultaneously realize protection of the internal circuit and securing a connection area for external connection. The protective layer 300 may be made of a photosensitive resin, and may be, for example, a solder resist layer, so as to perform a protective function in a subsequent mounting process.

Through this structure, the circuit board 10 may provide a stable transmission path for electrical signals while securing improved heat dissipation characteristics and interlayer adhesion by the carbon pattern layer 215. In addition, a high-performance and a high-reliability circuit board may be implemented through the circuit layer structure capable of forming a fine pattern and an effective protective layer structure.

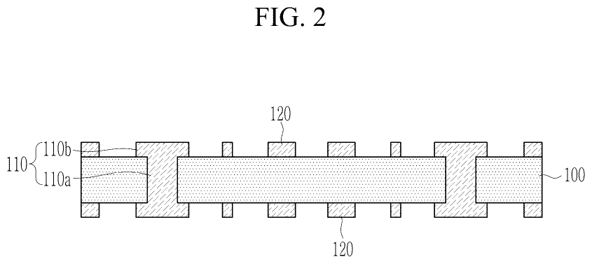

A method for manufacturing a circuit board 10 according to one embodiment will be described in detail step by step with reference to FIGS. 2 to 13 together with FIG. 1.

FIGS. 2 to 13 are process cross-sectional views illustrating a method for manufacturing a circuit board according to an embodiment.

First, referring to FIG. 2, a copper clad laminate (CCL) having a double-sided copper foil as the first insulating layer 100 is prepared, a through via hole is formed in a first direction perpendicular to the surface of the first insulating layer 100 through laser or mechanical drilling processing, and the through via 110 and the first circuit layer 120 are formed through a circuit formation process. The through via 110 may include the through portion 110a extending in the first direction to cover an inner wall of the through via hole, and the land portion 110b extending in a second direction intersecting the first direction from the through portion 110a.

The first insulating layer 100 may include a thermosetting or thermoplastic resin such as epoxy resin or polyimide. An insulating material may include inorganic fillers, organic fillers, and/or glass fibers (glass cloth, and/or glass fabric) to improve mechanical strength and thermal properties. In particular, dimensional stability at high temperatures may be secured by including materials having a low coefficient of thermal expansion (Low CTE) of less than 5 ppm. For example, insulation materials such as SR, ABF, FR-4, BT, RCC, and CCL may be used.

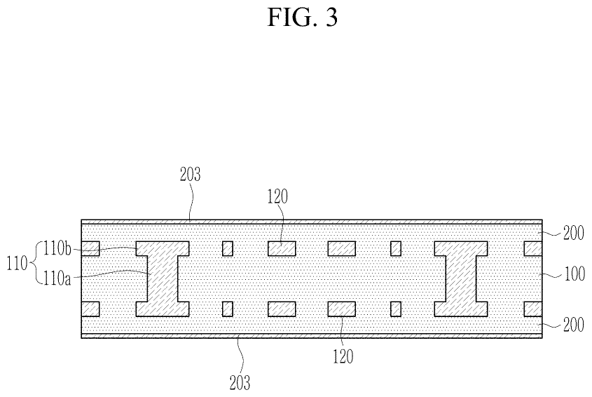

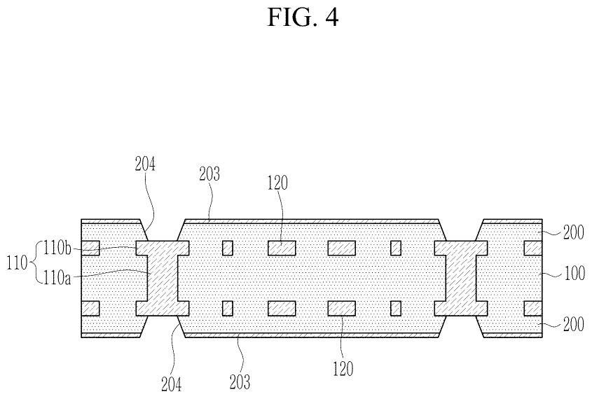

Referring to FIGS. 3 and 4, a prepreg without copper foil may be laminated on the first insulating layer 100 to form a second insulating layer 200, and a copper foil layer 203 may be formed thereon. The stack via hole 204 penetrating the second insulating layer 200 and the copper layer 203 formed on the second insulating layer 200 is formed. The stack via hole 204 may be formed by removing a portion of the copper layer 203 and the second insulating layer 200, thereby exposing a portion of the upper surface of the land portion 110b of the through via 110.

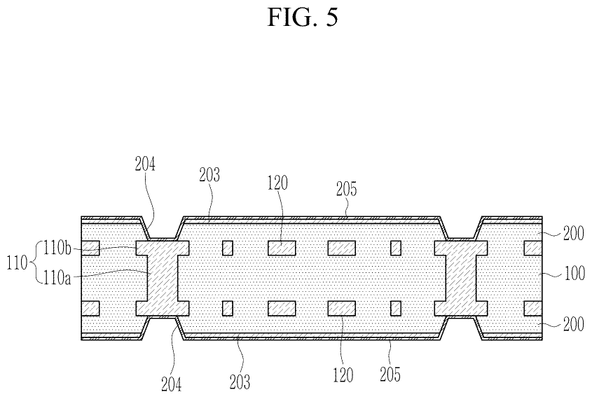

Referring to FIG. 5, a seed layer 205 is formed on an inner wall of the stack via hole 204 and a surface of the copper layer 203. The seed layer 205 may be formed through electroless plating. The seed layer 205 may also be formed on the land portion 110b of the through via 110 exposed by the stack via hole 204. The seed layer 205 serves as the basis for a subsequent electroplating process and enables the formation of a stable metal layer.

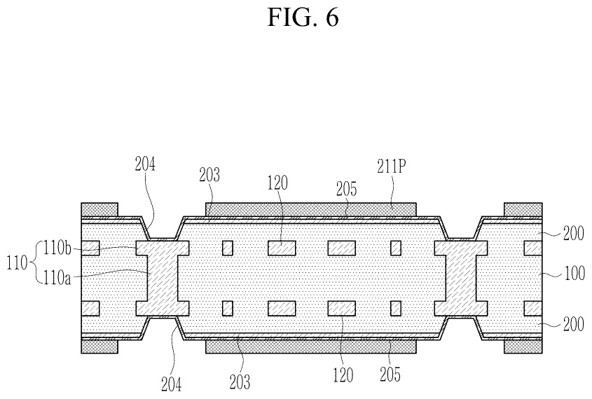

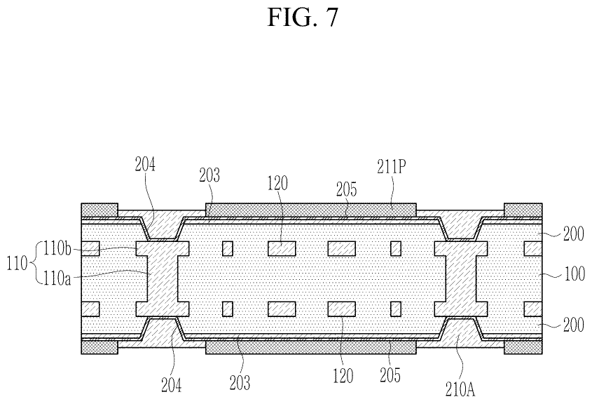

Referring to FIGS. 6 and 7, a photosensitive dry film is applied on the seed layer 205 to form a first mask pattern 211P, and a via formation layer 210A that fills the stack via hole 204 is formed through electroplating. The photosensitive dry film may be applied in negative type. The via formation layer 210A fills the stack via hole 204 and may be electrically connected to the land portion 110b of the through via 110. A material of the via formation layer 210A may be a conductive metal material such as copper, aluminum, silver, tin, gold, nickel, lead, titanium, or an alloy thereof, and may be implemented as a signal via, a ground via, or a power via depending on a circuit design.

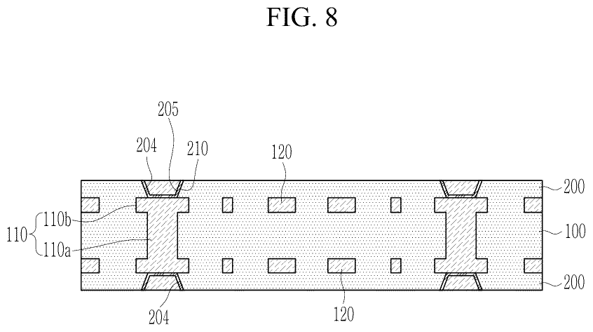

Referring to FIG. 8, the first mask pattern 211P is peeled off and the copper layer 203 and seed layer 205 formed on the second insulating layer 200 are removed through a polishing process. At this time, a portion of the via formation layer 210A protruding above the surface of the second insulating layer 200 may be removed to form the stack via 210, and a flat structure without a surface step may be implemented even near the via hole. This surface flattening enables uniform application of a liquid photosensitive material in a subsequent process, which may improve the reliability of fine pattern formation. Here, the liquid photosensitive material may be of positive type.

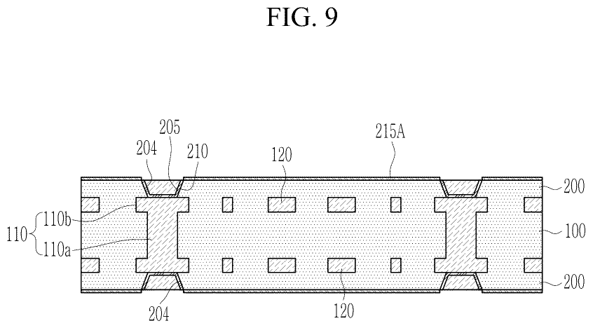

Referring to FIG. 9, a carbon layer 215A is formed by applying colloidal graphite on a surface of the flattened second insulating layer 200. The colloidal graphite is a liquid material in which fine graphite particles are dispersed in water or various organic solvents, and may be used to make the surfaces of non-metallic objects electrically conductive. The colloidal graphite may be applied to the surface of the second insulating layer 200 by, for example, immersion method, screen printing, or brush application. The carbon layer 215A may be formed through a drying process after application, and the carbon layer 215A may include a graphite layer.

To form a circuit on an insulating layer with a low coefficient of thermal expansion, colloidal graphite with a thickness of several nanometers may be applied instead of the conventional electroless plating and primer layer. The carbon layer 215A contains the same organic components as the insulating layer and thus has high chemical affinity, and thus may provide excellent interlayer adhesion without a separate primer layer, and due to its extremely thin thickness, it may not form additional surface steps. For example, the carbon layer 215A may have a thickness of less than 1 micrometer.

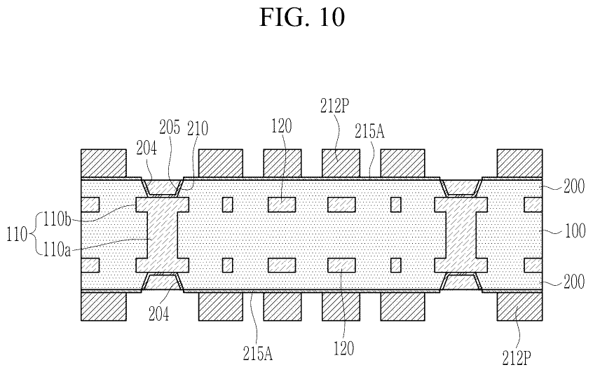

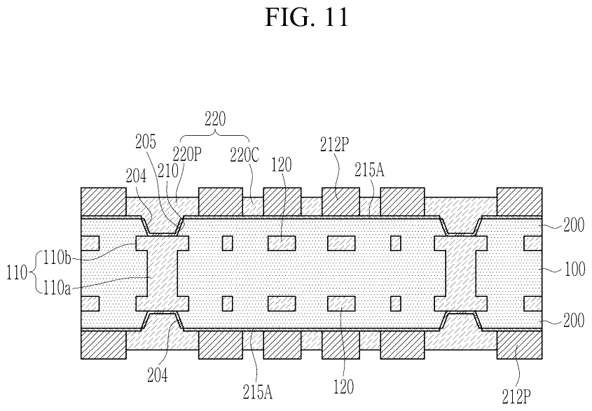

Referring to FIG. 10 and FIG. 11, a second mask pattern 212P is formed on the carbon layer 215A. The second mask pattern 212P may be formed by applying a positive type liquid photosensitive material and exposing and developing it. The use of a structure without surface steps and a positive liquid photosensitive material enables the implementation of a fine circuit pattern having a line width/spacing (L/S) of 100 nanometers or more and 5 micrometers or less. L/S indicates the line width of a circuit pattern and the spacing between lines on a PCB or semiconductor substrate. The second circuit layer 220 is formed through electrolytic plating in an area exposed by the second mask pattern 212P. The second circuit layer 220 formed through this may include the pad 220P and the circuit wiring 220C, and may be formed of a conductive metal material such as copper, aluminum, or silver. The second circuit layer 220 may be implemented with ground patterns, power patterns, signal patterns, etc. in the form of lines, planes, or pads.

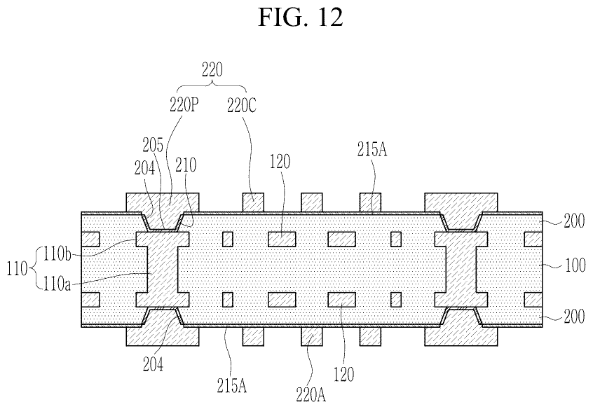

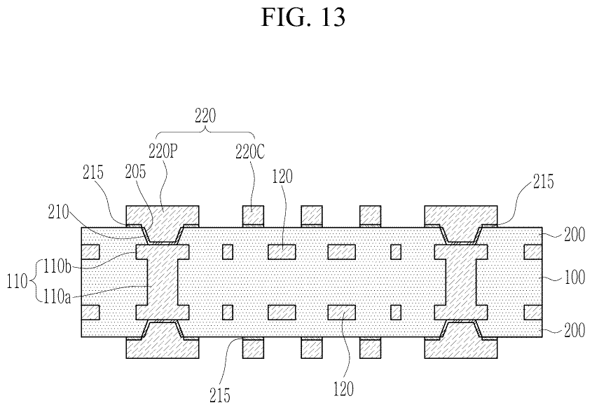

Referring to FIGS. 12 and 13, after forming the second circuit layer 220 through electroplating using the second mask pattern 212P, the second mask pattern 212P is removed and the carbon layer in an area where a circuit is not formed is selectively removed using a mixed solution of water and ethanol. At this time, the carbon layer 215A under the second circuit layer 220 remains as the carbon pattern layer (215), which may improve adhesion between the circuit layer and the insulating layer and improve heat dissipation characteristics.

Referring FIG. 1, the protective layer 300, which is a solder resist layer made of a photosensitive resin, is formed to protect the second circuit layer 220 from the external environment. The protective layer 300 covers one surface of the second insulating layer 200 and may expose at least a portion of the pad 220P to provide a connection area for external connection.

This manufacturing method may provide the following technical effects:

First, excellent adhesion is secured through the carbon layer even on insulating materials with a low coefficient of thermal expansion, so a separate primer layer is unnecessary. In addition, uniform application of positive liquid photosensitive material is possible through via filling and surface flattening, and stable implementation of microcircuits with a line width/spacing of 5/5 micrometers or less, which is the semiconductor level, is possible. In addition, this fine pattern implementation technology enables the deletion of the interposer in the POP (Package on Package) structure, thereby simultaneously achieving a reduction in the thickness of the entire package and an improvement in performance. As a result, the manufacturing method of the present embodiment enables the manufacturing of next-generation circuit boards with high integration, high reliability, and high performance.

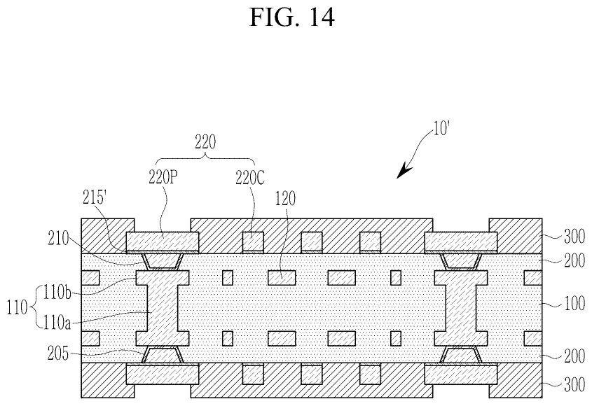

FIG. 14 is a cross-sectional view schematically illustrating a structure of a circuit board according to another embodiment.

Referring to FIG. 14, a circuit board 10′ according to another embodiment may include a first insulating layer 100, a first circuit layer 120, a through via 110, a second insulating layer 200, a second circuit layer 220, and a carbon pattern layer 215′ to provide a stable transmission path of an electrical signal through a multilayer wiring structure.

The second circuit layer 220 is disposed on the second insulating layer 200 and may include a pad 220P and circuit wiring 220C. The pad 220P of the second circuit layer 220) may be stably connected to the first circuit layer 120 through the stack via 210 penetrating the second insulating layer 200.

In another embodiment, the carbon pattern layer 215′ may be disposed between the second circuit layer 220 and a surface of the second insulating layer 200. The carbon pattern layer 215′ may be disposed between the pad 220P and the surface of the second insulating layer 200, or between the circuit wiring 220C and the surface of the second insulating layer 200. The carbon pattern layer 215′ positioned between the pad 220P and the surface of the second insulating layer 200 may extend between the pad 220P and the stacked via 210.

The carbon pattern layer 215′ is a layer that stably forms the second circuit layer 220 on the second insulating layer 200. The carbon pattern layer 215′ may include conductive graphite and effectively contribute to securing adhesion of the second circuit layer 220 to the second insulating layer 200. The carbon pattern layer 215′ may not exist on a surface of the second insulating layer 200 where the pad 220P or the circuit wiring 220C is not disposed.

The structure of the insulating layer and circuit layer other than the parts described above may be configured similarly to the circuit board described with reference to FIG. 1, so redundant description is omitted below.

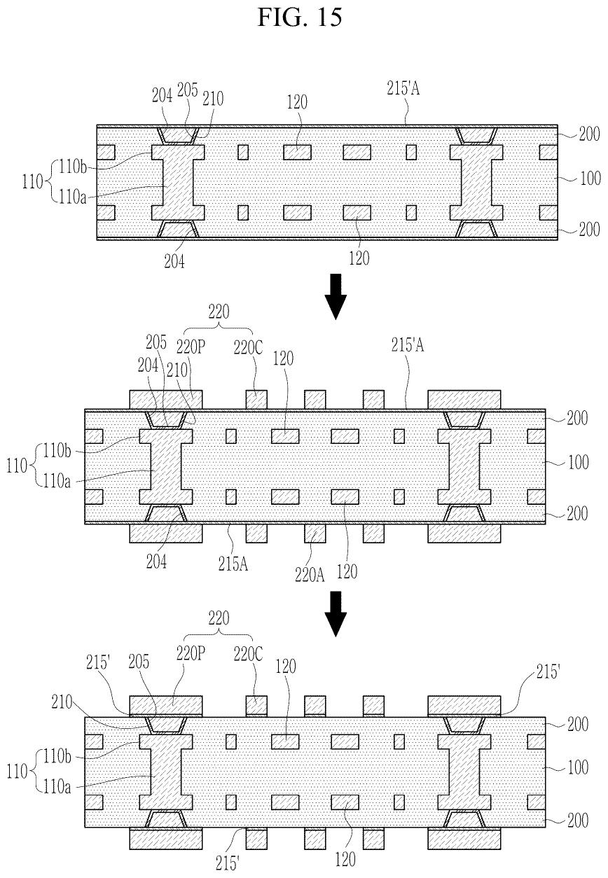

FIG. 15 is a process cross-sectional view illustrating a method for manufacturing the circuit board shown in FIG. 14.

As described with reference to FIGS. 2 to 8, the first insulating layer 100, the first circuit layer 120, the second insulating layer 200, the through via 110, and the stack via 210 are formed through the circuit forming process, and the polishing process is performed to remove the copper layer 203 and the seed layer 205 on the second insulating layer 200 to flatten the surface.

Referring to FIG. 15, a carbon layer 215′A is formed by applying colloidal graphite on a surface of the flattened second insulating layer 200. The colloidal graphite is a liquid material in which fine graphite particles are dispersed in water or various organic solvents, and may be used to make the surfaces of non-metallic objects electrically conductive. The colloidal graphite may be applied to the surface of the second insulating layer 200 by, for example, immersion method, screen printing, or brush application. The carbon layer 215′A may be formed through a drying process after application, and the carbon layer 215A may include a graphite layer.

Next, a positive type liquid photosensitive material used in a semiconductor process is applied, a mask pattern is formed through exposure and development, and the second circuit layer 220 is formed through electrolytic plating in an area exposed by the mask pattern. The second circuit layer 220 formed through this may include the pad 220P and the circuit wiring 220C, and may be formed of a conductive metal material such as copper, aluminum, or silver.

Next, after forming the second circuit layer 220, the mask pattern is removed and the carbon layer in the area where the circuit is not formed is selectively removed using a mixed solution of water and ethanol. At this time, the carbon layer 215′A under the second circuit layer 220 remains as the carbon pattern layer 215′, which may improve adhesion between the circuit layer and the insulating layer and improve heat dissipation characteristics.

Referring to FIG. 14, a protective layer 300, which is a solder resist layer made of a photosensitive resin, is formed to protect the second circuit layer 220 from the external environment. The protective layer 300 covers one surface of the second insulating layer 200 and may expose at least a portion of the pad 220P to provide a connection area for external connection.

While embodiments of the present invention have been described above, the present disclosure is not limited thereto, and it is possible to perform various modifications within the scope of the claims, the detailed description, and the accompanying drawings, and it is natural that these modifications also fall within the scope of the present disclosure.

What is claimed is:

1. A circuit board comprising:
an insulating layer having a via hole;
a via filling the via hole;
a circuit layer disposed on the insulating layer, and comprising a pad connected to the via and a circuit wiring spaced apart from the pad; and
a carbon pattern layer disposed between the circuit layer and a surface of the insulating layer.

2. The circuit board of claim 1, wherein
the carbon pattern layer comprises a graphite layer.

3. The circuit board of claim 1, wherein
the circuit layer comprises a metal layer, and the carbon pattern layer is disposed between the metal layer and the insulating layer.

4. The circuit board of claim 1, wherein
the carbon pattern layer does not exist on a surface of the insulating layer where the pad or the circuit wiring is not disposed.

5. The circuit board of claim 1, wherein
the insulating layer comprises a first insulating layer having a through via hole penetrating in a first direction, and a second insulating layer covering the first insulating layer and having a stack via hole, and
wherein the via fills the stack via hole and comprises a stack via that penetrates the second insulating layer.

6. The circuit board of claim 5, wherein
the via comprises a through via that fills the through via hole and is connected to the stack via.

7. The circuit board of claim 6, wherein
the through via comprises:
a through portion filling the through via hole; and
a land portion extending from the through portion in a second direction intersecting the first direction and disposed on the first insulating layer.

8. The circuit board of claim 7, wherein
the stack via penetrates the second insulating layer and is connected to the land portion of the through via.

9. The circuit board of claim 7, wherein
the circuit layer comprises a first circuit layer disposed on the first insulating layer and spaced apart from the land portion, and a second circuit layer disposed on the second insulating layer, and
the carbon pattern layer is disposed at the second circuit layer adjacent to a surface of the second insulating layer.

10. The circuit board of claim 1, wherein
the carbon pattern layer is disposed between the pad and the surface of the insulating layer.

11. The circuit board of claim 1, wherein
the carbon pattern layer is disposed between the circuit wiring and the surface of the insulating layer.

12. A manufacturing method of a circuit board, comprising:
forming a via hole penetrating an insulating layer;
forming a seed layer on a surface of the insulating layer in which the via hole is formed;
forming a first mask pattern on the first seed layer to expose the seed layer of the via hole and its surrounding area;
forming a via formation layer on the seed layer exposed by the first mask pattern;
exposing the insulating layer by removing the first mask pattern and the via formation layer disposed on the insulating layer;
applying a carbon layer to a surface of the exposed insulating layer;
forming a second mask pattern on the carbon layer;
forming a circuit layer on the carbon layer exposed by the second mask pattern;
exposing the carbon layer by removing the second mask pattern disposed on the carbon layer; and
removing the exposed carbon layer.

13. The manufacturing method of claim 12, wherein
the applying of the carbon layer comprises applying colloidal graphite.

14. The manufacturing method of claim 12, wherein
the forming of the second mask pattern comprises forming a positive photoresist by applying a positive liquid photosensitive material.

15. The manufacturing method of claim 12, wherein
the removing of the exposed carbon layer comprises removing the exposed carbon layer using a mixed solution of water and ethanol.

16. The manufacturing method of claim 12, wherein
the exposing of the insulating layer comprises removing the first mask pattern and at least a portion of the via formation layer through polishing.

17. The manufacturing method of claim 12, wherein:
the forming of the seed layer comprises forming the seed layer through electroless plating on the via hole and the surface of the insulating layer.

18. The manufacturing method of claim 12, wherein
the forming of the first mask pattern comprises forming a negative photoresist.

19. The manufacturing method of claim 12, wherein
the forming of the via formation layer comprises forming a via that fills an inside of the via hole.

20. The manufacturing method of claim 19, wherein
the insulating layer comprises a first insulating layer having a through via hole penetrating in a first direction, and a second insulating layer covering the first insulating layer and having a stack via hole, and
wherein the via fills the stack via hole and comprises a stack via that penetrates the second insulating layer.

21. The manufacturing method of claim 12,
wherein the insulating layer comprises a resin material,
and the carbon layer is formed directly on the resin material without a separate primer layer.

22. The circuit board of claim 1, wherein the insulating layer comprises a resin material,
and the carbon pattern layer is formed directly on the resin material without a separate primer layer.
